(19) United States
(12) Patent Application Publication
(10) Pub. No.: US 2026/0047091 A1
(43) Pub. Date: Feb. 12, 2026

(54) METHODS AND APPARATUSES FOR OPERATING A MEMORY SYSTEM

(71) Applicant: Yangtze Memory Technologies Co., Ltd., Wuhan (CN)

(72) Inventors: Yixun ZHOU, Wuhan (CN); Hao HOU, Wuhan (CN)

(21) Appl. No.: 18/885,264

(22) Filed: Sep. 13, 2024

Related U.S. Application Data
(63) Continuation of application No. PCT/CN2024/110907, filed on Aug. 9, 2024.

(51) Int. Cl. H10B 41/41; H01L 25/18; H10B 43/35; H10B 80/00; H10N 79/00

(52) U.S. Cl. CPC H10B 41/41; H01L 25/18; H10B 43/35; H10B 80/00; H10N 79/00

(57) ABSTRACT

Methods, devices, and systems for managing memory devices are provided. In one aspect, a memory system can include a memory device including memory cells, a memory controller coupled to the memory device, a power loss protection (PLP) circuit, and a discharge circuit coupled to an output of the PLP circuit. The discharge circuit includes one or more discharge paths configured to discharge at least one of the PLP circuit, the memory device, or the memory controller.

### CROSS-REFERENCE TO RELATED APPLICATIONS

This application is a continuation of International Application No. PCT/CN2024/110907, filed on Aug. 9, 2024, the disclosure of which is hereby incorporated by reference in its entirety.

### TECHNICAL FIELD

The present disclosure generally relates to memory devices and memory systems, and in particular, to managing power discharge in memory systems.

### BACKGROUND

Flash memory is a low-cost, high-density, nonvolatile solid-state storage medium that can be electrically erased and reprogrammed. Flash memory includes NOR flash memory and NAND flash memory. Various operations can be performed by flash memory, for example, program (write) and erase operations, to change the threshold voltage of each memory cell to a respective level. For NAND flash memory, an erase operation can be performed at the memory block level, a program operation can be performed at the page level, and a read operation can be performed at the page level.

### SUMMARY

The present disclosure involves methods, apparatuses, and systems for managing temperature in a memory system. One aspect of the present disclosure features a memory system including a memory device including memory cells, a memory controller coupled to the memory device, a power loss protection (PLP) circuit, and a discharge circuit coupled to an output of the PLP circuit. The discharge circuit includes one or more discharge paths configured to discharge at least one of the PLP circuit, the memory device, or the memory controller.

In some implementations, a first discharge path of the one or more discharge paths includes a first resistor coupled to the output of the PLP circuit, and a first transistor coupled to a first switch transistor. A gate of the first switch transistor is coupled to a first voltage dividing circuit. The first voltage dividing circuit is configured to generate a divided voltage of the output of the PLP circuit. A terminal of the first switch transistor is coupled to the output of the PLP circuit.

In some implementations, the first voltage dividing circuit includes two resistors connected in series. A first end of the first voltage dividing circuit is coupled to the output of the PLP circuit, and a second end of the first voltage dividing circuit is coupled to ground.

In some implementations, a second discharge path of the one or more discharge paths includes a second resistor coupled to an enable pin of a voltage converter configured to activate the voltage converter, and a second transistor coupled to the first switch transistor. The voltage converter is configured to generate a voltage for the memory controller based on the output of the PLP circuit.

In some implementations, a third discharge path of the one or more discharge paths includes a third resistor coupled to the memory device, and a third transistor coupled to the first switch transistor.

In some implementations, the PLP circuit includes a capacitor. The PLP circuit is configured to charge the capacitor when an external power source is turned on, and discharge the capacitor to provide power for the memory system when the external power source is turned off.

In some implementations, a fourth discharge path of the one or more discharge paths includes a fourth resistor coupled to the output of the PLP circuit, and a fourth transistor coupled to a second switch transistor. A gate of the second switch transistor is coupled to the first voltage dividing circuit. A terminal of the second switch transistor is coupled to a second voltage dividing circuit configured to generate a divided voltage of a voltage of the capacitor.

In some implementations, a fifth discharge path of the one or more discharge paths includes a fifth resistor coupled to the capacitor, and a fifth transistor coupled to the second switch transistor.

In some implementations, the memory device, the memory controller, the PLP circuit and the discharge circuit are placed on a printed circuit board. The discharge circuit is distanced from the PLP circuit on the printed circuit board.

In some implementations, the discharge circuit is coupled to at least one of a capacitor of the PLP circuit, an enable pin of a voltage converter, and the memory device.

One aspect of the present disclosure features a memory system including a memory device including memory cells, a memory controller coupled to the memory device, a power loss protection (PLP) circuit configured to provide power for the memory system when an external power source is turned off, and a discharge circuit. The discharge circuit is configured to, in response to determining that an output voltage of the PLP circuit is lower than a first threshold, discharge at least one of the PLP circuit, the memory device or the memory controller.

In some implementations, the discharge circuit includes one or more discharge paths each including a transistor and a resistor.

In some implementations, discharging at least one of the PLP circuit, the memory device or the memory controller includes the following operations: discharging the PLP circuit through a first discharge path of the discharge circuit, discharging a first voltage line through a second discharge path of the discharge circuit, where the first voltage line is configured to activate a voltage converter configured to generate a voltage for the memory controller based on the output voltage of the PLP circuit, and discharging a second voltage line through a third discharge path of the discharge circuit. The second voltage line is configured to provide power for the memory device.

In some implementations, the PLP circuit includes a capacitor. The discharge circuit is configured to, in response to determining that the output voltage of the PLP circuit is lower than a second threshold and that a voltage of the capacitor is higher than a third threshold, discharge the PLP circuit through a fourth discharge path of the discharge circuit, and discharge the capacitor through a fifth discharge path of the discharge circuit.

In some implementations, the discharge circuit is configured to, in response to determining that the output voltage of the PLP circuit is higher than a fourth threshold and lower than the first threshold, discharge the PLP circuit through the first discharge path.

In some implementations, the first discharge path, the second discharge path and the third discharge path are coupled to a first switch transistor. A gate of the first switch transistor is coupled to a first voltage dividing circuit configured to generate a divided voltage of the output voltage of the PLP circuit. A terminal of the first switch transistor is coupled to an output of the PLP circuit.

In some implementations, the fourth discharge path and the fifth discharge path are coupled to a second switch transistor. A gate of the second switch transistor is coupled to the first voltage dividing circuit. A terminal of the second switch transistor is coupled to a second voltage dividing circuit that is configured to generate a divided voltage of a voltage of the capacitor.

One aspect of the present disclosure features a method of discharging a memory system. The method includes, in response to determining that an output voltage of a power loss protection (PLP) circuit of the memory system is lower than a first threshold, discharging, by a discharge circuit, at least one of the PLP circuit, a memory device of the memory system, or a memory controller of the memory system. The discharge circuit is distanced from the PLP circuit.

In some implementations, discharging at least one of the PLP circuit, the memory device or the memory controller includes, in response to determining that the output voltage of the PLP circuit is lower than the first threshold, discharging the PLP circuit through a first discharge path of the discharge circuit. Discharging at least one of the PLP circuit, the memory device or the memory controller further includes, in response to determining that the output voltage of the PLP circuit is lower than a second threshold and that a voltage of a capacitor of the PLP circuit is higher than a third threshold, discharging the PLP circuit through a fourth discharge path of the discharge circuit.

In some implementations, the method further includes, in response to determining that the output voltage of the PLP circuit is higher than a fourth threshold and lower than the first threshold, discharging the PLP circuit through the first discharge path.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates a block diagram of an example system having a memory device, according to some aspects of the present disclosure.

FIGS. 2A-2B illustrate example storage products, according to some aspects of the present disclosure.

FIG. 3 illustrates an example of a schematic diagram of a memory device including peripheral circuits, according to some aspects of the present disclosure.

FIG. 4 illustrates some example peripheral circuits, according to some aspects of the present disclosure.

FIG. 5 illustrates a block diagram of a memory controller interacting with a host and a memory device, according to some aspects of the present disclosure.

FIG. 6 illustrates an example memory system including a discharge circuit, according to some aspects of the present disclosure.

FIG. 7A illustrates a schematic circuit diagram of an example discharge circuit of FIG. 6, according to some aspects of the present disclosure.

FIG. 7B illustrates a schematic circuit diagram of an example voltage converter of FIG. 6, according to some aspects of the present disclosure.

FIG. 8 illustrates a schematic circuit diagram of an example PLP circuit of FIG. 6, according to some aspects of the present disclosure.

FIG. 9A illustrates performances of a memory system without a discharge circuit during a power-off process, according to some aspects of the present disclosure.

FIG. 9B illustrates performances of a memory system having a discharge circuit during a power-off process, according to some aspects of the present disclosure.

FIG. 10A illustrates performances of a memory system without a discharge circuit during a power-on process, according to some aspects of the present disclosure.

FIG. 10B illustrates performances of a memory system having a discharge circuit during a power-on process, according to some aspects of the present disclosure.

FIG. 11 illustrates a flow chart of an example method of operating a memory system, according to some aspects of the present disclosure.

Like reference numbers and designations in the various drawings indicate like elements.

### DETAILED DESCRIPTION

This specification relates to memory devices, memory systems, and methods for managing power discharge in a memory system (e.g., a solid state drive). When an external power source of the memory system is disconnected, the memory system can perform power loss protection to ensure data integrity. After completing power loss protection, the memory system needs to discharge its residual electrical power. As such, components of the memory system can be powered off following a specified sequence. Further, when the external power source is reconnected, the components of the memory system can be powered on following a specified sequence. If residual electrical power is not fully discharged, the memory system may encounter disorder in the power-off sequence and the power-on sequence, which may cause malfunction in the memory system.

In some cases, a memory system discharges its residual electrical power using an auto discharge function integrated into a power management chip, such as a power loss protection (PLP) chip, or a power management integrated circuit (PMIC) chip. However, the integrated auto discharge function may only discharge limited components in the memory system, and the discharge speed may not be fast enough. Further, the integrated auto discharge function may not be able to discharge the memory system in an event that the external power source is connected but unstable (e.g., the voltage jitters or oscillates).

The present disclosure provides techniques to discharge the memory system using a discharge circuit. The discharge circuit can be a discrete circuit in the memory system, rather than being integrated into the power management chip. The discharge circuit can be configured to discharge residual electrical power of multiple components of the memory system. In some implementations, the discharge circuit is also configured to discharge the accumulated electrical power in the memory system in an event that the external power source is connected but unstable, so that the unstable power source does not disturb the power-on sequence of the memory system.

The described techniques can achieve one or more technical effects. For example, the memory system can fully and rapidly discharge its residual electrical power by using the discharge circuit. As such, the power-off sequence and the power-on sequence of the memory system can be kept in order. For another example, since the discharge circuit can be a discrete circuit comprising resistors and transistors, its design can be tailored to meet discharge requirements of different memory systems. Compared to designing a customized power management chip that can meet certain discharge requirements, the described techniques are more cost-effective. Further, the described techniques can not only discharge the memory system when the external power source is disconnected, but can also discharge the memory system when the external power source is connected but unstable, which can make the memory system more reliable. In some implementations, additional or different technical effects can be achieved.

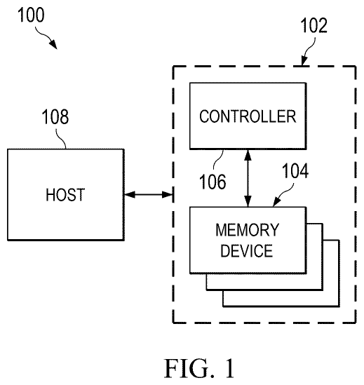

FIG. 1 illustrates a block diagram of an example system 100 having a memory device, according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include a host 108 and a memory system 102 having one or more memory devices 104 and a memory controller 106. The host 108 can include one or more processors of an electronic device. The processor can be a central processing unit (CPU), or a system-on-chip (SoC), such as an application processor (AP). The host 108 can be configured to send or receive data and commands to or from the memory systems 102.

The memory device 104 can be any memory device disclosed in the present disclosure, such as a NAND Flash memory device. It is noted that the NAND Flash is only one example of memory device for illustrative purposes. It can include any suitable solid-state, non-volatile memory, e.g., NOR Flash, Ferroelectric RAM (FeRAM), Phase-change memory (PCM), Magne-to-resistive random-access memory (MRAM), Spin-transfer torque magnetic random-access memory (STT-RAM), or Resistive random-access memory (RRAM), etc. In some implementations, memory device 104 includes a three-dimensional (3D) NAND Flash memory device.

The memory controller 106 can be implemented by microprocessors, microcontrollers (a.k.a. microcontroller units (MCUs)), digital signal processors (DSPs), application-specific integrated circuits (ASICs), field-programmable gate arrays (FPGAs), programmable logic devices (PLDs), state machines, gated logic, discrete hardware circuits, and other suitable hardware, firmware, and/or software configured to perform the various functions described below in detail.

The memory controller 106 is coupled to the memory device 104 and to the host 108, and is configured to control the memory device 104, according to some implementations. The memory controller 106 can manage the data stored in the memory device 104 and can communicate with the host 108. In some implementations, the memory controller 106 is designed for operating in a low duty-cycle environment, such as secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, logical-to-physical mapping management, wear leveling, etc. In some implementations, the memory controller 106 is further configured to process error correction codes (ECCs) with respect to the data read from or written to the memory device 104. Any other suitable functions can be performed by the memory controller 106 as well, for example, formatting the memory device 104.

The memory controller 106 can communicate with an external device (e.g., the host 108) according to a particular communication protocol. For example, the memory controller 106 can communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc. The memory controller 106 is configured to receive and transmit a command to and from the host 108, and execute or perform multiple functions and operations provided in the present disclosure, which will be described later.

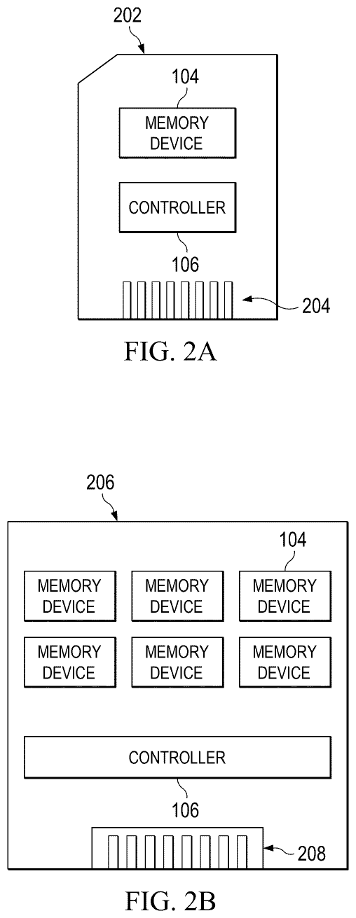

The memory controller 106 and the one or more memory devices 104 can be integrated into various types of storage devices. For example, the memory controller 106 and the one or more memory devices 104 can be packaged in a universal Flash storage (UFS) package or an eMMC package. In one example as shown in FIG. 2A, the memory controller 106 and a single memory device 104 can be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 204 coupling the memory card 202 with a host (e.g., host 108 in FIG. 1). In another example as shown in FIG. 2B, the memory controller 106 and multiple memory devices 104 can be integrated into an SSD 206. The SSD 206 can further include an SSD connector 208 that couples the SSD 206 with a host (e.g., host 108 in FIG. 1). In some implementations, the storage capacity and/or the operation speed of the SSD 206 is greater than those of the memory card 202.

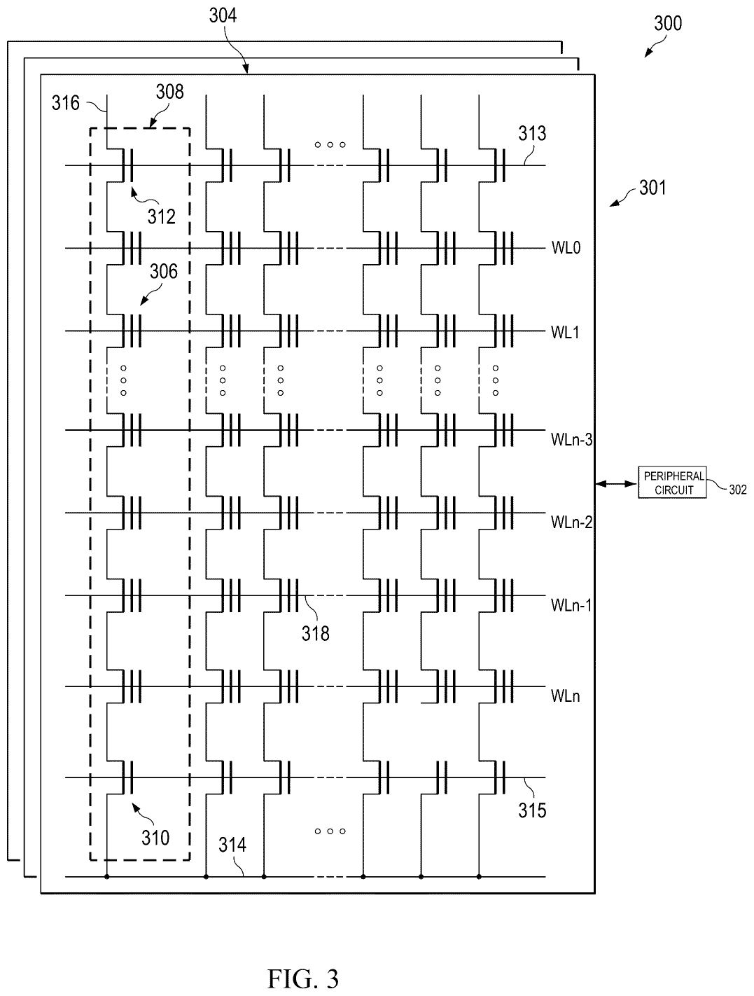

FIG. 3 illustrates an example of a schematic diagram of a memory device 300 including peripheral circuits, according to some aspects of the present disclosure. The memory device 300 can include a memory cell array 301 and peripheral circuits 302 coupled to the memory cell array 301. The memory cell array 301 can be a NAND Flash memory cell array in which memory cells 306 are provided in the form of an array of NAND memory strings 308 each extending vertically above a substrate (not shown in FIG. 3). In some implementations, each NAND memory string 308 includes a plurality of memory cells 306 coupled in series and stacked vertically. Each memory cell 306 can hold a continuous, analog value, such as an electrical voltage or charge that depends on the number of electrons trapped within a storage layer of the memory cell 306. The logic state (i.e., data) of each memory cell 306 in a memory block 304 can be determined based on the threshold voltage Vth of the memory cell 306. Each memory cell 306 can be a floating gate type memory cell including a floating-gate transistor, or a charge trap type memory cell including a charge-trap transistor.

In some implementations, each memory cell 306 is a single-level cell (SLC) with two possible memory states that can store one bit of data. For example, the first memory state “0” can correspond to a first range of voltages, and the second memory state “1” can correspond to a second range of voltages. In some implementations, each memory cell 306 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 3, each NAND memory string 308 can include a source select gate (SSG) 310 at its source end and a drain select gate (DSG) 312 at its drain end. The SSG 310 and the DSG 312 can be configured to activate selected NAND memory strings 308 (columns of the array) during read and program operations. In some implementations, the sources of NAND memory strings 308 in the same memory block 304 are coupled through a same source line (SL) 314, e.g., a common SL. In other words, NAND memory strings 308 in the same memory block 304 have an array common source (ACS), according to some implementations. The DSG 312 of each NAND memory string 308 is coupled to a respective bit line 316 from which data can be read or written via an output bus (not shown), according to some implementations. In some implementations, each NAND memory string 308 is configured to be selected or deselected by applying a select voltage (e.g., above the threshold voltage of the transistor having the DSG 312) or a deselect voltage (e.g., 0 V) to the respective DSG 312 through one or more DSG lines 313, and/or by applying a select voltage (e.g., above the threshold voltage of the transistor having the SSG 310) or a deselect voltage (e.g., 0 V) to the respective SSG 310 through one or more SSG lines 315.

As shown in FIG. 3, NAND memory strings 308 can be organized into multiple memory blocks 304, each of which can have a common SL 314 coupled to the ACS. In some implementations, each memory block 304 can serve as a basic data unit for erase operations, such that memory cells 306 on the same memory block 304 are erased at the same time. To erase memory cells 306 in a selected memory block 304, the SL 314 coupled to the selected memory block 304 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 306 of adjacent NAND memory strings 308 can be coupled through word lines 318. The word line 318 can select which row of memory cells 306 is affected by read and program operations. Each word line 318 can include a gate line coupled to a plurality of control gates (gate electrodes) of a plurality of memory cells 306. Example word lines shown in FIG. 3 include WL0, WL1, WLn−3, WLn−2, WLn−1 and WLn that are between one or more DSG lines 313 and one or more SSG lines 315.

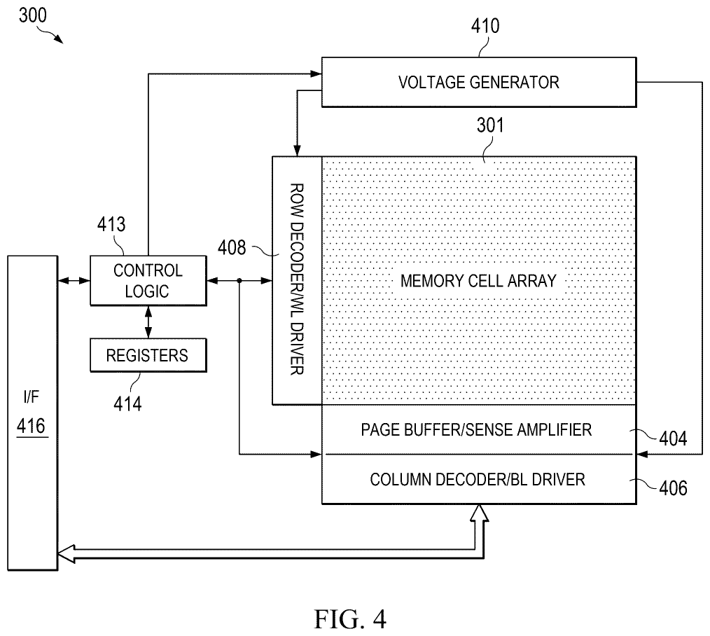

FIG. 4 illustrates some example peripheral circuits 302, according to some aspects of the present disclosure. The peripheral circuits 302 can be coupled to the memory cell array 301 through bit lines 316, word lines 318, SLs 314, SSG lines 315, and DSG lines 313. The peripheral circuits 302 can include any suitable analog, digital, and mixed-signal circuits for facilitating the operations of the memory cell array 301 by applying and sensing voltage signals and/or current signals to and from each target memory cell 306 through bit lines 316, word lines 318, SLs 314, SSG lines 315, and DSG lines 313. The peripheral circuits 302 can include various types of peripheral circuits formed using metal-oxide-semiconductor (MOS) technologies. The example peripheral circuits 302 include a page buffer/sense amplifier 404, a column decoder/bit line driver 406, a row decoder/word line driver 408, a voltage generator 410, control logic 412, registers 414, an interface 416, and a data bus. In some examples, additional peripheral circuits not shown in FIG. 4 may be included as well.

The page buffer/sense amplifier 404 can be configured to read and program (write) data from and to memory cell array 301 according to the control signals from control logic 412. In an example, the page buffer/sense amplifier 404 may store one page of program data (write data) to be programmed into one page of the memory cell array 301. In another example, the page buffer/sense amplifier 404 may perform program verify operations to ensure that the data have been properly programmed into memory cells 306 coupled to selected word lines 418. In still another example, the page buffer/sense amplifier 404 may also sense the low power signals from the bit line 316 that represents a data bit stored in memory cell 306, and amplify the small voltage swing to recognizable logic levels in a read operation. The column decoder/bit line driver 406 can be configured to be controlled by the control logic 412 and select one or more NAND memory strings 308 by applying bit line voltages generated from the voltage generator 410.

The row decoder/word line driver 408 can be configured to be controlled by the control logic 412 and select/deselect memory blocks 304 of the memory cell array 301 and select/deselect word lines 418 of the memory block 304. The row decoder/word line driver 408 can be further configured to drive word lines 418 using word line voltages generated from the voltage generator 410. In some implementations, the row decoder/word line driver 408 can also select/deselect and drive SSG lines 315 and DSG lines 313. As described below in detail, the row decoder/word line driver 408 is configured to apply a program voltage to selected word line 418 in a program operation on memory cell 306 coupled to selected word line 418.

The voltage generator 410 can be configured to be controlled by the control logic 412 and generate the word line voltages (e.g., read voltage, program voltage, pass voltage, local voltage, verify voltage, etc.), bit line voltages, and source line voltages to be supplied to the memory cell array 301.

The control logic 412 can be coupled to each peripheral circuit described above and configured to control operations of each peripheral circuit. The registers 414 can be coupled to the control logic 412 and include status registers, command registers, and address registers for storing status information, command operation codes (OP codes), and command addresses for controlling the operations of each peripheral circuit.

The interface 416 can be coupled to the control logic 412 and act as a control buffer to buffer and relay control commands received from a host (not shown) to the control logic 412 and status information received from the control logic 412 to the host. The interface 416 can also be coupled to the column decoder/bit line driver 406 via a data bus, and act as a data input/output (I/O) interface and a data buffer to buffer and relay data to and from the memory cell array 301.

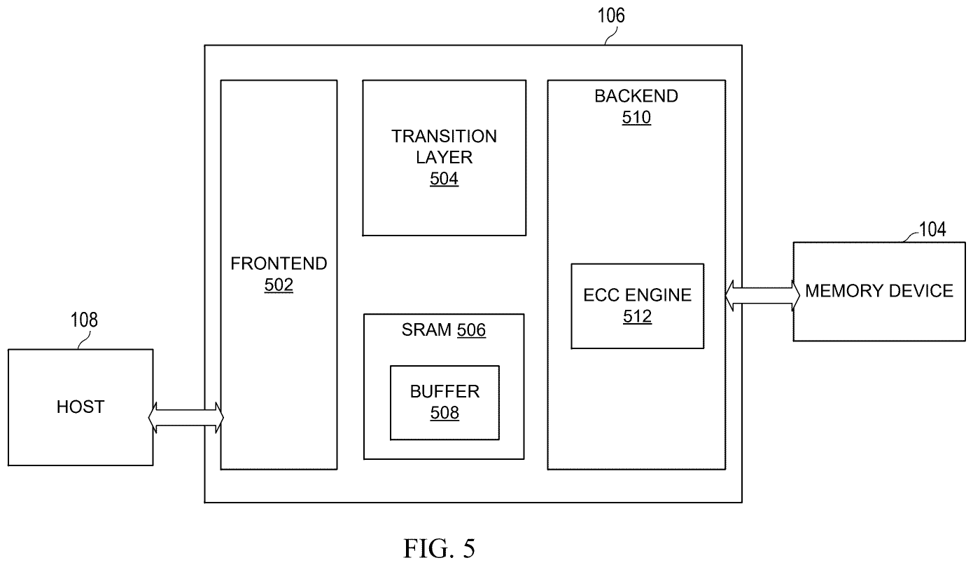

FIG. 5 illustrates an example of a block diagram of a memory controller 106 interacting with a host 108 and a memory device 104, according to some aspects of the present disclosure.

The memory controller can include a frontend 502, a transition layer 504, a Static Random-Access Memory (SRAM) 506, and a backend 510. The SRAM 506 can include one or more buffers 508. The backend 510 can include an error-correction code (ECC) engine 512. In some examples, additional components not shown in FIG. 5 may be included in the memory controller 106 as well.

The frontend 502 can be configured to handle communications between the host 108 and the memory controller 106. In some implementations, the frontend 502 can communicate with the host 108 according to a particular communication protocol. For example, the frontend 502 can communicate with the host 108 through at least one of various interface protocols, such as a USB protocol, an MMC protocol, a PCI protocol, a PCI-E protocol, an ATA protocol, a serial-ATA protocol, a parallel-ATA protocol, a SCSI protocol, an ESDI protocol, an IDE protocol, a Firewire protocol, etc. In some implementations, the frontend 502 can receive a request from the host 108 and forward the request to the backend 510 via the transition layer 504, so that the backend 510 can fulfill the request. Examples of a request can include, but are not limited to, a read request to read data stored in a block of memory device 104, a write request to erase data stored in a block of memory device 104 and to write new data into the block, a reformatting request to reformat the memory device 104, or any other suitable request. In some implementations, the frontend 502 can receive data from the backend 510 via the transition layer 504, and send the data to the host 108.

The transition layer 504 can be configured to handle communications between the frontend 502 and the backend 510. The transition layer 504 can act as an intermediate layer between the frontend 502 and the backend 510.

The backend 510 can be configured to fulfill requests from host 108. In some implementations, backend 510 can receive a request from the host 108 via the frontend 502 and the transition layer 504, and perform one or more operations to fulfill the request. For example, backend 510 can be configured to control operations of memory device 104 (e.g., read, erase, or program operations) in response to receiving a request from host 108 (e.g., a read request, an erasing request, or a programming request). The backend 510 can also be configured to manage various functions with respect to the data stored or to be stored in the memory device 104 including, but not limited to, bad-block management, error correction, or garbage collection, etc.

The ECC engine 512 in the backend 510 can be configured to process error correction codes with respect to the data read from or written to the memory device 104. Example error correction codes can include, but are not limited to, Hamming codes, Reed-Solomon codes, low-density parity check (LDPC) codes, etc. For example, the backend 510 can read data from a block of memory device 104 in response to a read request, and process error correction codes to determine whether data stored in the block is read successfully (e.g., with no errors). If the data stored in the block is read successfully, the backend 510 can forward the data to the frontend 502 via the transition layer 504, so that the frontend 502 can return the data to the host 108. However, if the data stored in the block is not read successfully, the backend 510 can generate data describing a read error on the block.

In some implementations, the ECC engine 512 can be further configured to handle the read error on the block. For example, the ECC engine 512 can be configured to implement a set of error handling mechanisms to handle the read error on the block. If the data stored in the block can be read successfully by applying the set of error handling mechanisms, the ECC engine 512 can return the data to host 108. In some cases, if the data stored in the block cannot be read successfully by applying the set of error handling mechanisms, the ECC engine 512 can perform a memory test on the block to determine whether the block malfunctions (e.g., whether the block is a bad block). The ECC engine 512 can update a mapping table of memory device 104 by adding a newly discovered bad block to the mapping table. The mapping table can be used to record any bad blocks of memory device 104, and can be stored in memory device 104 or a storage medium of memory controller 106.

The SRAM 506 can be configured to temporarily store data transmitted between the host 108 and the memory device 104. For example, as the host 108 writes data into memory device 104, or the host 108 reads data from the memory device 104, the SRAM 506 can temporarily store page data corresponding to one word line, or parity data corresponding to one word line. The SRAM 506 can include one or more buffers 508, such as a parity buffer configured to store parity data and garbage collection (GC) data, a read buffer configured to temporarily store data that are read from the memory device 104, and/or a copy buffer configured to temporarily store data to be written to the memory device 104, or the like.

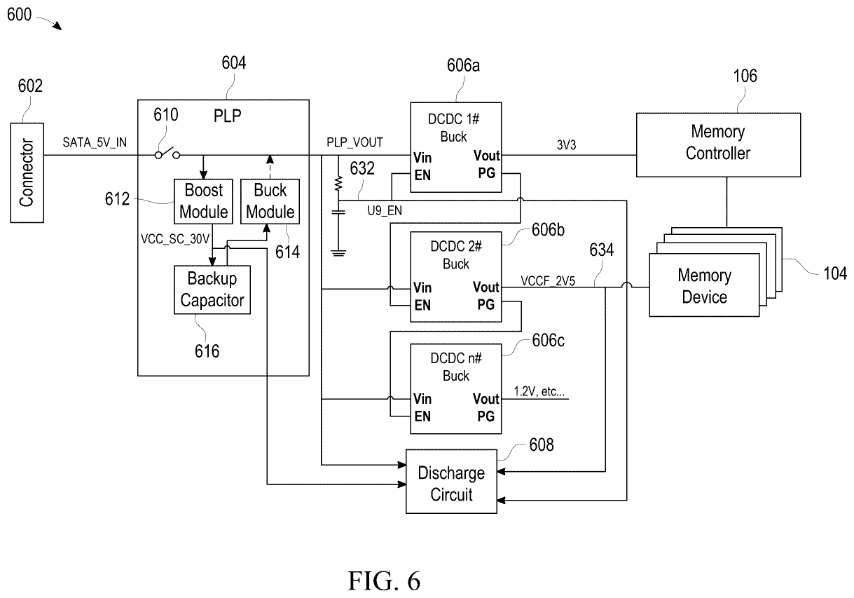

FIG. 6 illustrates a block diagram of a memory system 600 including a discharge circuit 608, according to some aspects of the present disclosure. The memory system 600 can include a connector 602, a power loss protection (PLP) circuit 604, one or more voltage converters 606a, 606b, 606c (collectively 606), a discharge circuit 608, a memory controller 106, and a memory device 104.

The connector 602 is configured to connect the memory system 600 to a host (e.g., host 108 of FIG. 1), for example, to a computer's motherboard. In some implementations, the connector 602 is connected to the host according to a particular interface, such as a Serial ATA (SATA) interface. The connector 602 can include a set of pins (e.g., 7 pins) used for data transmission, and a set of pins (e.g., 15 pins) used for power supply. For example, the connector 602 can deliver a power of 5V to the memory system 600.

The PLP circuit 604 can be configured to provide power for the memory system 600 in case of an unexpected power loss. The PLP circuit 604 can include a load switch 610, a boost module 612, a buck module 614, and a backup capacitor 616. The PLP circuit 604 is coupled to the connector 602. When power is delivered to the PLP circuit 604 from the connector 602, the load switch 610 is turned on, so that the PLP circuit 604 can deliver power to the voltage converters 606. In addition, the boost module 612 can elevate the voltage of the power from the connector 602 to a higher voltage, for example, from 5V to 30V, and charge the backup capacitor 616 with the higher voltage. When no power is delivered to the PLP circuit 604 from the connector 602, for example, when memory system 600 is disconnected from the host, the load switch 610 is turned off. In such case, the backup capacitor 616 can discharge its electrical energy to provide power for the memory system 600, so that the memory system 600 can complete unfinished operations (e.g., pending write operations) to maintain data integrity. In some implementations, the buck module 614 is configured to lower the voltage of the power discharged by the backup capacitor to a voltage suitable to power the memory system 600, for example, from 30V to 3-5V. Once external power is restored, for example, when the memory system 600 is reconnected to the host, the backup capacitor 616 can be recharged to be ready for a future power loss.

A voltage converter 606 (e.g., a DC-DC converter) can be configured to convert an input voltage (e.g., the output voltage of the PLP circuit 604) to an output voltage that is suited to power a specific component of the memory system 600. The memory system 600 can include a set of voltage converters 606 connected in series. Each voltage converter 606 can include an input pin 622 connected to the output of the PLP circuit 604, an enable pin 624 configured to activate or deactivate the voltage converter 606, an output pin 626 connected to a voltage line that powers a specific component of the memory system 600, and a status pin 628 (e.g., power good (PG) pin) that indicates that power of the voltage converter is good. The enable pin 624 of the first voltage converter 606a is connected to a voltage line 632 that generates a voltage based on the output of the PLP circuit 604. When the output of the PLP circuit 604 reaches a threshold, the first voltage converter 606a can be activated. In some implementations, except for the first voltage converter 606a, the enable pin 624 of a voltage converter 606 is connected to the status pin 628 of the preceding voltage converter 606. For example, when the power of first voltage converter 606a is good, its status pin 628 can output a high voltage. The enable pin 624 of the second voltage converter 606b can receive the high voltage, which indicates to activate the second voltage converter 606b. When the power of the second voltage converter 606b is good, its status pin 628 can output a high voltage. The enable pin 624 of the third voltage converter 606c can receive the high voltage, which indicates to activate the third voltage converter 606c, and so on. As such, the voltage converters 606 connected in series can be activated sequentially.

In some implementations, as shown in FIG. 6, the first voltage converter 606a is configured to convert the output voltage of the PLP circuit 604 to a first voltage (e.g., 3.3 V) suited to power the memory controller 106. The output pin 626 of the first voltage converter 606a can be connected to a voltage line that provides power for the memory controller 106. The second voltage converter 606b is configured to convert the output voltage of the PLP circuit 604 to a second voltage (e.g., 2.5 V) suited to power the memory device 104. The output pin 626 of the second voltage converter 606b can be connected to a voltage line 634 that provides power for the memory device 104. The third voltage converter 606c is configured to convert the output voltage of the PLP circuit 604 to another voltage (e.g., 1.2V) suited to power another component of the memory system 600. In some implementations, the memory system can include a different number of voltage converters 606.

The discharge circuit 608 can be configured to discharge the memory system 600, for example, after the PLP circuit 604 provides necessary power for the memory system 600 to complete power loss protection. The discharge circuit 608 can be coupled to the output of the PLP circuit 604 so that the discharge circuit 608 can be activated or deactivated based on the output voltage of the PLP circuit 604. The discharge circuit can be further coupled to the backup capacitor 616, the voltage line 632, and the voltage line 634 for discharging. In some implementations, the discharge circuit 608 can be coupled to additional or different components of the memory system.

In some implementations, under the scenario where the external power source is turned off, when the output voltage of the PLP circuit 604 drops below a first threshold (e.g., a voltage between 2.5V and 3.8V), the discharge circuit 608 is activated to discharge the output of the PLP circuit 604, the backup capacitor 616, the voltage line 632 and the voltage line 634. In some implementations, under the scenario where the external power source is turned on but unstable (e.g., the voltage jitters or oscillates), the discharge circuit 608 can also be activated to discharge the output of the PLP circuit 604. Otherwise, the output of the PLP circuit 604 may accumulate to a voltage level as a result of the unstable power supply, which may erroneously activate some components of the memory system before power is stable.

In some implementations, the discharge circuit 608 is a discrete circuit, rather than being integrated with the PLP circuit 604 into a single chip. For example, the memory device 104, the memory controller 106, the PLP circuit 604 and the discharge circuit 608 are placed on a printed circuit board. The discharge circuit 608 can be distanced from the PLP circuit 604 on the printed circuit board.

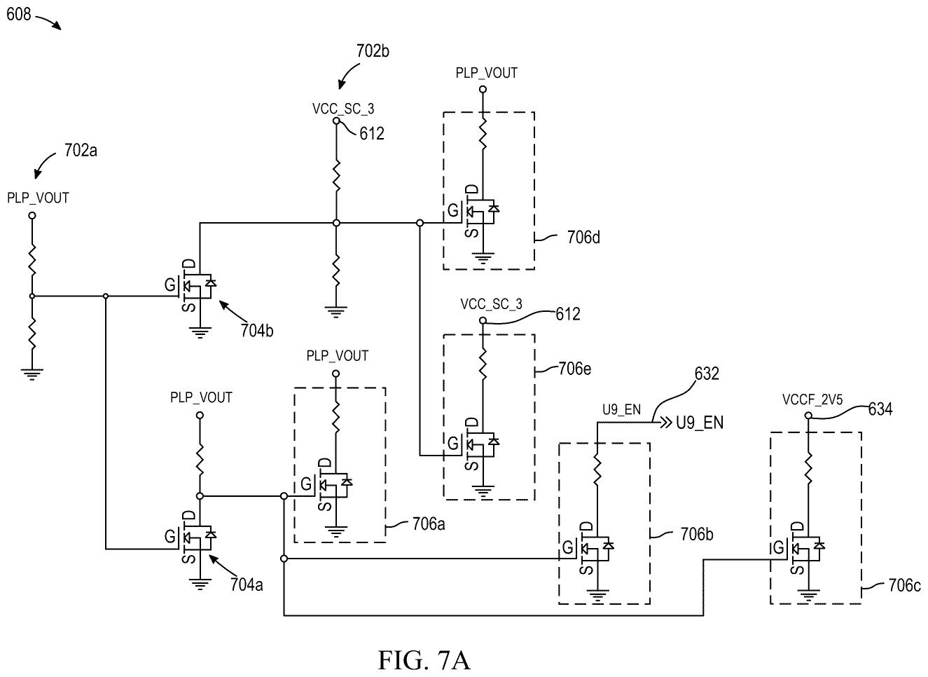

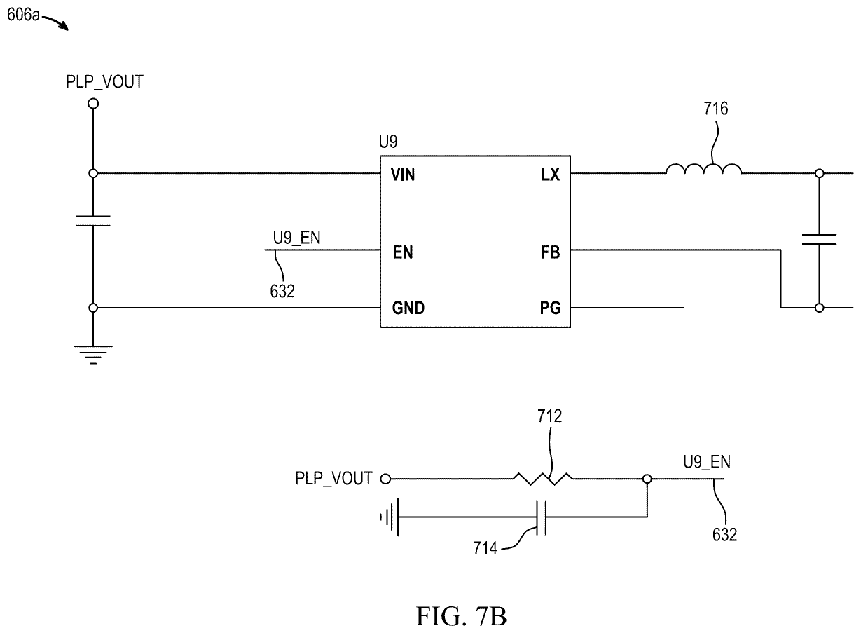

FIG. 7A illustrates a schematic circuit diagram of an example discharge circuit 608 of FIG. 6, according to some aspects of the present disclosure. The discharge circuit 608 can include one or more voltage dividing circuits 702, one or more switch transistors 704, and one or more discharge paths 706.

Each voltage dividing circuit 702 can include two resistors connected in series. The voltage dividing circuit 702 can generate a divided voltage (Vout) of the input voltage (Vin), such as

$${V}_{out} = \frac{R 1}{( R 1 + R 2 )} {V}_{in} ,$$

where R1 and R2 are the resistance of the two resistors.

Each discharge path 706 can include a transistor and a resistor connected in series. The transistor can have a terminal (e.g., gate) of the transistor can be connected to a control voltage (for example, to an output voltage of a voltage dividing circuit 702, or to a switch transistor 704), a terminal (e.g., source) connected to ground, and a terminal (e.g., drain) connected to one end of the resistor. The other end of the resistor can be coupled to a component or a voltage line to be discharged. For example, as shown in FIG. 7A, the first discharge path 706a is coupled to the output of the PLP circuit 604; the second discharge path 706b is coupled to the voltage line 632, which is connected to the enable pin 624 of the first voltage converter 606a; the third discharge path 706c is coupled to the voltage line 634, which is configured to provide power to the memory device 104; the fourth discharge path 706d is coupled to the output of the PLP circuit 604; and the fifth discharge path 706e is coupled to the backup capacitor 616.

In some implementations, as shown in FIG. 7A, the first voltage dividing circuit 704a has a first end coupled to the output of the PLP circuit 604 and a second end coupled to ground. The first voltage dividing circuit 702a can generate a divided voltage of the output voltage of the PLP circuit 604. Gates of the first switch transistor 704a and the second switch transistor 704b are coupled to the first voltage dividing circuit 702a to receive the divided voltage of the output voltage of the PLP circuit 604. The gate of the transistor in each of the first discharge path 706a, the second discharge path 706b, and the third discharge path 706c is connected to a terminal (e.g., drain) of the first switch transistor 704a.

In addition, the second voltage dividing circuit 702b has one end connected to the backup capacitor 616 and another end connected to ground. The second voltage dividing circuit 702b can generate a divided voltage of the backup capacitor 616. The gate of the transistor in each of the fourth discharge path 706d and the fifth discharge path 706e is connected to the output of the second voltage dividing circuit 702b to receive the divided voltage of the backup capacitor 616.

For example, under the scenario where the external power source is turned off, the PLP circuit 604 outputs a voltage (e.g., 5V) for a certain period of time (e.g., 50-200 ms), so that the memory system can complete unfinished operations to protect data integrity. During such time, the output of the first voltage dividing circuit 702a is higher than the threshold voltage (e.g., a voltage between 0.5V and 1.3V) of the first switch transistor 704a and the second switch transistor 704b. The first switch transistor 704a and the second switch transistor 704b are switched on, so that all discharge paths 706 are switched off. After the power loss protection is completed, the output voltage of the PLP circuit 604 can drop below the first threshold (e.g., a voltage between 2.5V and 3.8V), so that the output voltage of the first voltage dividing circuit 702a is lower than the threshold voltage of the first switch transistor 704a and the second switch transistor 704b. The first switch transistor 704a and the second switch transistor 704b are switched off, so that the first to fifth discharge circuits 706a-706e are switched on to discharge corresponding components or voltage lines of the memory system 600.

During the discharge process, since the output of the PLP circuit 604 may also discharge through the voltage converters 606, the output of the PLP circuit 604 may discharge faster than the backup capacitor 616. In some implementations, when the output voltage of the PLP circuit 604 drops below a second threshold (e.g., a voltage between 0.5V and 1.5V), the voltage of the backup capacitor 616 is still relatively high, for example, higher than a third threshold (e.g., a voltage between 1.2V to 2.5V). In such case, the first discharge path 706a, the second discharge path 706b, and the third discharge path 706c may be deactivated, while the fourth discharge path 706d and the fifth discharge path 706e may remain activated (since the fourth discharge path 706d and the fifth discharge path 706e are triggered by the divided voltage of the backup capacitor 616). As such, the discharge circuit 608 can continue to discharge the output of the PLP circuit 604 through the fourth discharge path 706d. After the voltage of the backup capacitor 616 drops below the third threshold, the fourth discharge path 706d and the fifth discharge path 706e are deactivated.

For another example, under the scenario where the external power source is turned on but unstable (e.g., the voltage jitters or oscillates), the output of the PLP circuit 604 may increase to be higher than a fourth threshold (e.g., a voltage between 1V and 2V) but lower than the first threshold, as a result of the accumulation of the unstable power supply. Since the unstable power supply may not be able to charge the backup capacitor 616, the voltage of the backup capacitor 616 may remain low, so that the fourth discharge path 706d may not be activated. Meanwhile, the first discharge path 706a can be activated to discharge the output of the PLP circuit 604. As such, in the event of unstable power supply, the output voltage of the PLP circuit 604 does not increase to a level that is high enough to activate a voltage converter 606. Therefore, different components of the memory system 600 are powered on in an orderly sequence after the external power source stabilizes. Otherwise, if a voltage converter 606 is prematurely activated before the external power source stabilizes, subsequent voltage converters 606 may also be prematurely activated. As a result, the overall power-up sequence may erroneously shift forward, and an inrush current during the power-up process may increase.

In some implementations, the circuit design of the discharge circuit 608 may be adjusted, e.g., based on actual discharge needs of the memory system. For example, the discharge circuit 608 can include more discharge paths configured to discharge other components of the memory system (e.g., a DRAM coupled to the memory controller, a SRAM of the memory controller, a peripheral circuit of the memory device, etc.). For another example, by adjusting the first voltage dividing circuit 702a and/or the switch transistors 704, the discharge paths 706 can be activated in response to that output voltage of the PLP circuit 604 has dropped below a different threshold. For instance, by using two resistors with a greater difference in resistance in the first voltage dividing circuit 702a, and/or by using transistors with higher threshold voltages as the first switch transistor 704a and the second switch transistors 704b, the discharge paths 706 can be activated at an earlier stage during the voltage drop of the output of the PLP circuit 604.

FIG. 7B illustrates a schematic circuit diagram of an example voltage converter 606 of FIG. 6, according to some aspects of the present disclosure. The voltage converter 606 can include an input pin (VIN) connected to the output of the PLP circuit 604, an enable pin (EN) configured to activate the voltage converter 606, a ground pin (GND) connected to ground, an inductor pin (LX) connected to an inductor 716, a feedback pin (FB) configured to monitor the output voltage, and a status pin (PG) that provides an indication of whether the output voltage is within a specified range. In some implementations, the enable pin of the first voltage converter 606a of a series of voltage converters 606 is coupled to the voltage line 632. A resistor 712 and a capacitor 714 are coupled in series between the output of the PLP circuit 604 and ground, and the voltage line 632 is drawn out between the resistor and the capacitor. In some implementations, the voltage at the inductor pin switches between the input voltage (e.g., voltage at VIN) and ground voltage (e.g., voltage at GND) at a high frequency, in order to transfer energy from the input to the output through the inductor 716. In some implementations, the feedback pin can be configured to monitor the output voltage and compare it with a reference voltage. The feedback pin can maintain a stable output voltage by adjusting the duty cycle of a switching transistor coupled to the inductor 716.

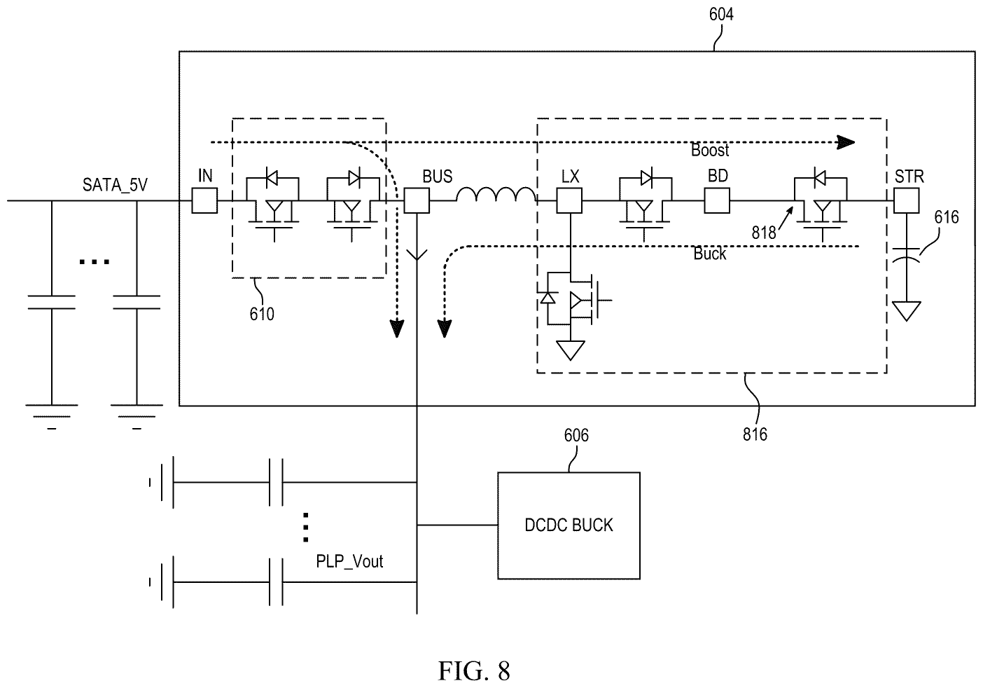

FIG. 8 illustrates a schematic circuit diagram of an example PLP circuit 604 of FIG. 6, according to some aspects of the present disclosure. The PLP circuit can include a load switch 610, a bi-directional DC-DC circuit 816, and a backup capacitor 616. An input of the PLP circuit 604 can be coupled to the external power source, for example, through the connector 602. The load switch 610 can include one or more switch transistors.

In some implementations, when external power source is connected, the load switch 610 is turned on to connect the PLP circuit 604 to the external power source. In such case, the PLP circuit 604 can deliver the power to the rest of the memory system, for example, through a series of voltage converters 606. The PLP circuit 604 can also charge the backup capacitor 616 through the bi-directional DC-DC circuit 816. For example, along a first current direction of the bi-directional DC-DC circuit 816, the voltage from external power source (e.g., 5V) can be boosted to a higher voltage (e.g., 30V) to charge the backup capacitor 616. After the backup capacitor 616 is fully charged, a disconnect switch 818 can be switched off to disconnect the backup capacitor 616 from the bi-directional DC-DC circuit 816, so that electrical energy can be stored in the backup capacitor 616.

In some implementations, when the external power source is disconnected, the load switch 610 is turned off, and the disconnect switch 818 is turned on to discharge the backup capacitor 616 through the bi-directional DC-DC circuit 816. For example, along a second current direction of the bi-directional DC-DC circuit 816, the voltage of the backup capacitor 616 (e.g., 30V) can be bucked to a lower voltage (e.g., a voltage between 3.5V and 5V) to power the rest of the memory system to complete power loss protection (e.g., to complete unfinished operations). After the power loss protection has been completed, the voltage of the backup capacitor 616 drops to a low level (e.g., from 30V to around 3.5V). That is, the backup capacitor still has residual electrical power, which can be discharged through the fifth discharge path 706c. By discharging the residual electrical power, the memory system can be powered off in an orderly sequence, so that the memory system can be powered on in an orderly sequence when the external power source is reconnected.

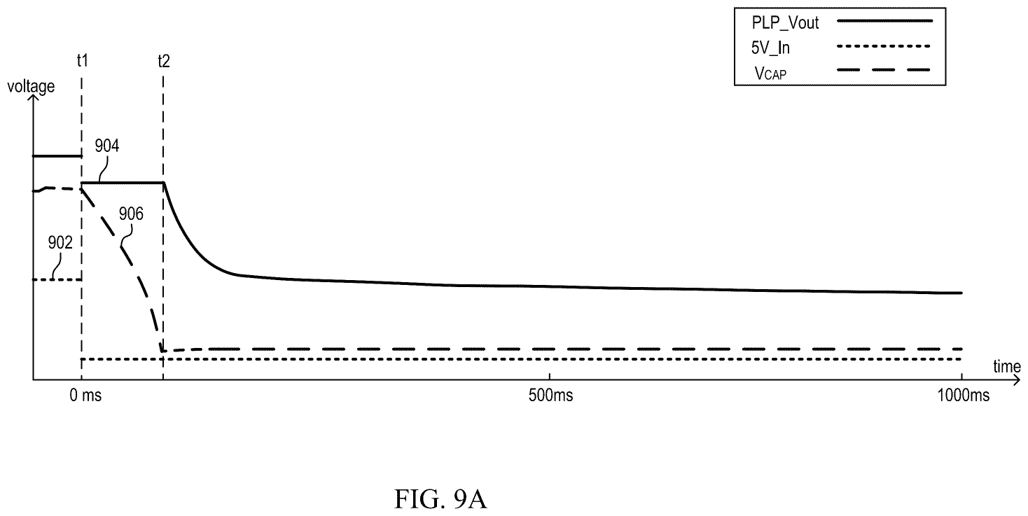

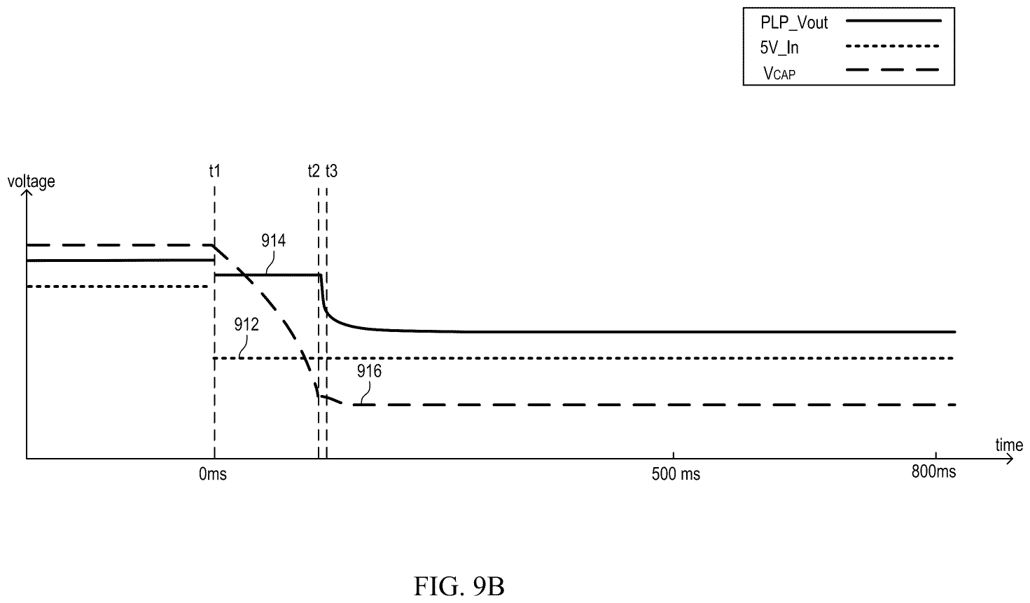

FIG. 9A illustrates performances of a memory system without a discharge circuit during a power-off process, according to some aspects of the present disclosure. In some cases, residual power in some components of the memory device cannot be fully discharged, and power discharge in some components may take a long time.

Att1, an external power source is disconnected. Input voltage 902 of a PLP circuit of the memory system drops to 0V. Between t1 and t2, output voltage 914 of the PLP circuit can be maintained at a steady level (e.g., around 3.8V), for example, by discharging the backup capacitor of the PLP circuit to power the memory system for power loss protection. Voltage 906 of the backup capacitor decreases between t1 and t2.

At t2, the power loss protection is completed, and the output voltage 904 of the PLP circuit starts to decrease. Since the memory system does not have a discharge circuit, the residual power in the backup capacitor may not be further discharged after t2, and the output of the PLP circuit can only discharge by itself slowly. For example, as shown in FIG. 9A, voltage 906 of the backup capacitor remains at a level (e.g., around 4V) after t2. The output voltage 904 of the PLP circuit decreases slowly after t2. In some cases, after about 1 second from t2, the output of the PLP circuit may still not be discharged fully, and the output voltage 904 of the PLP circuit may still be around 500 mV.

FIG. 9B illustrates performances of a memory system having a discharge circuit (e.g., the discharge circuit 608 of FIGS. 6 and 7A) during a power-off process, according to some aspects of the present disclosure. In some cases, residual power in the memory device can be fully and rapidly discharged.

Similar to FIG. 9A, at t1, an external power source is disconnected. Input voltage 912 of a PLP circuit of the memory system drops to 0V. Between t1 and t2, output voltage 904 of the PLP circuit can be maintained at a steady level (e.g., around 3.8V), for example, by discharging the backup capacitor of the PLP circuit to power the memory system for power loss protection. Voltage 916 of the backup capacitor decreases between t1 and t2.

At t2, power loss protection is completed, and output voltage 904 of the PLP circuit can discharge by itself. At t3, the output voltage 914 of the PLP circuit is below the first threshold, so that discharge paths (e.g., discharge paths 706 of FIG. 7A) of the discharge circuit are activated. Starting from t3, the output of the PLP circuit, the backup capacitor, and other components in the memory system can discharge rapidly through the discharge circuit. For example, as shown in FIG. 9B, voltage 916 of the backup capacitor can further decrease after t3. The output voltage 914 of the PLP circuit decreases rapidly after t3. In some cases, in about 200 ms from t3, the output of the PLP circuit is fully discharged, such that the output voltage 914 of the PLP circuit decreases to around 0V.

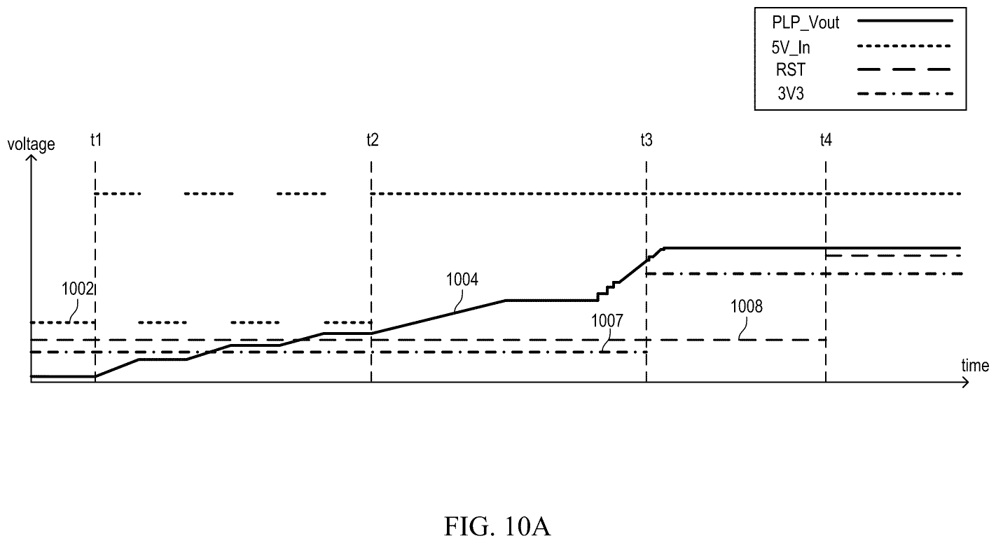

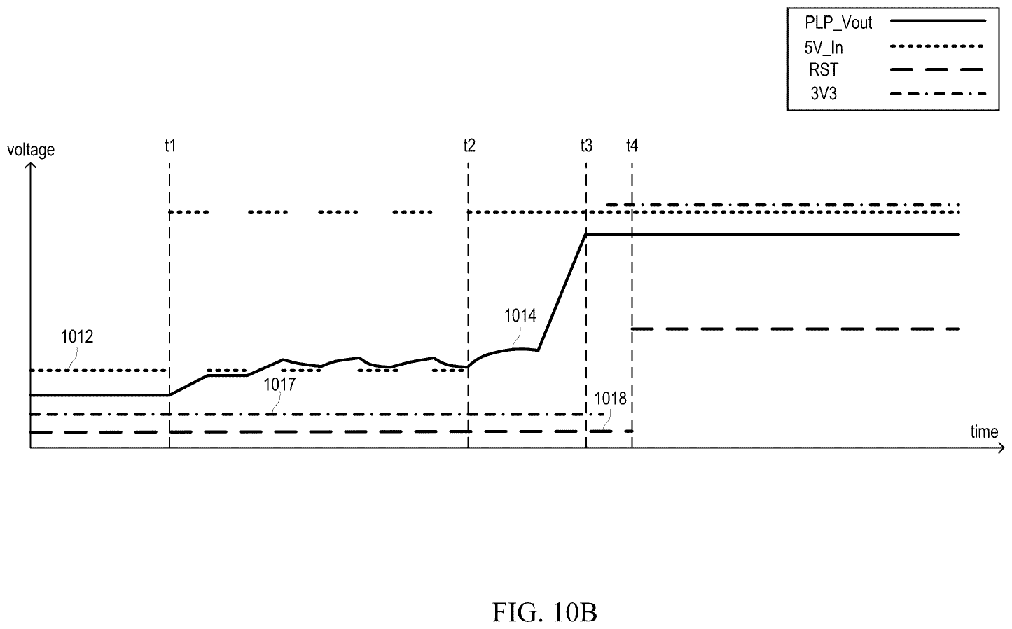

FIG. 10A illustrates performances of a memory system without a discharge circuit during a power-on process, according to some aspects of the present disclosure. In some cases, when the external power source is connected but unstable, the power-up sequence in the memory system may be disordered.

At t1, an external power source is connected. Between t1 and t2, the external power source is unstable, such that input voltage 902 of a PLP circuit of the memory system jitters between a high voltage and a low voltage. Since the memory system does not have a discharge circuit, the output voltage 1004 of the PLP circuit gradually increases between t1 and t2 as a result of the accumulation of the unstable input voltage 1002.

At t2, the external power source stabilizes at the high voltage. The output voltage 1004 of the PLP circuit is already accumulated to a certain level at t2. Therefore, starting from t2, it takes a shorter time to boost the output voltage 1004 of the PLP circuit to a level that activates a voltage converter (e.g., the voltage converter 606 of FIG. 6). In some cases, as shown in FIG. 10A, the voltage converter configured to provide power to the memory controller (e.g., memory controller 106 of FIG. 6) is activated at t3, such that the voltage converter starts to output voltage 1007 at t3. However, at t3, the output voltage 1004 of the PLP circuit is still increasing, and has not reached a stable level yet. As a result, the power-up sequence in the memory system becomes disordered. For example, the reset signal 1008 can be prematurely set high at t4 to indicate that all components of the memory system are powered on, while some components of the memory system may not be properly powered on yet at t4.

FIG. 10B illustrates performances of a memory system having a discharge circuit (e.g., the discharge circuit 608 of FIGS. 6 and 7A) during a power-on process, according to some aspects of the present disclosure. In some cases, when the external power source is connected but unstable, the power-up sequence in the memory system can be kept in order.

At t1, an external power source is connected. Between t1 and t2, the external power source is unstable, such that input voltage 902 of a PLP circuit of the memory system jitters between a high voltage and a low voltage. Since the memory system includes the discharge circuit to discharge the output of the PLP circuit, the output voltage 1014 of the PLP circuit remains at a low level, rather than accumulating to a high level as shown in FIG. 10A.

Att2, the external power source stabilizes at the high voltage. Starting from t2, the output voltage 1014 of the PLP circuit gradually increases from the low level to a stable level. The output voltage 1014 of the PLP circuit stabilizes at the stable level at t3. None of the voltage converters (e.g., the voltage converter 606 of FIG. 6) are activated before t3. For example, as shown in FIG. 10B, the voltage converter configured to provide power to the memory controller (e.g., memory controller 106 of FIG. 6) is activated at a time after t3, such that the voltage converter starts to output voltage 1017 after t3. As a result, by having the discharge circuit, the power-up sequence in the memory system can be kept in order. For example, the reset signal 1018 can be correctly set high at t4 to indicate that all components of the memory system are powered on.

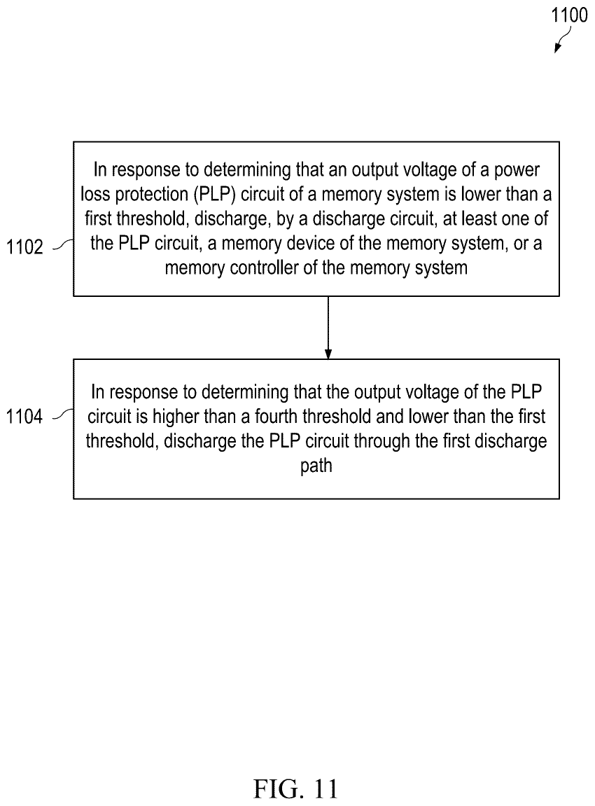

FIG. 11 illustrates a flow chart of an example method 1100 of operating a memory system, according to some aspects of the present disclosure. Method 1100 can be performed by any suitable device or system as described herein, for example, according to the example techniques described with respect to FIGS. 1-8, 9B and 10B. For example, method 1100 can be performed by a memory system, such as the memory system 600 of FIG. 6 that includes a PLP circuit 604, a discharge circuit 608, voltage converters 606, a memory controller 106 and a memory device 104.

The operations shown in method 1100 may not be exhaustive and that other operations can be performed as well before, after, or in between any of the illustrated operations. Further, some of the operations may be performed simultaneously, or in a different order than shown in FIG. 11. In some implementations, some of the operations may be performed by one or more components of a device or a system, such as, a discharge circuit of the memory system.

At 1102, in response to determining that an output voltage of the PLP circuit is lower than a first threshold (e.g., a voltage between 2.5V and 3.8V), the discharge circuit discharges at least one of the PLP circuit, the memory device, or the memory controller.

For example, during a power-off process when external power source is disconnected, after the PLP circuit provides necessary power to the rest of the memory system for power loss protection, the output voltage of the PLP circuit decreases. When the output voltage of the PLP circuit decreases below the first threshold, discharge paths (e.g., discharge paths 706 of FIG. 7A) can be activated. In some implementations, one or more discharges paths (e.g., the first discharge path 706a and the fourth discharge path 706d of FIG. 7A) are configured to discharge the output of the PLP circuit, one or more discharges paths (e.g., the second discharge path 706b of FIG. 7A) are configured to discharge a voltage line (e.g., voltage line 632 of FIG. 6) connected to an enable pin of a voltage converter (e.g., the first voltage converter 606a of FIG. 6), one or more discharges paths (e.g., the third discharge path 706c of FIG. 7A) are configured to discharge a voltage line (e.g., voltage line 634 of FIG. 6) configured to provide power for the memory device, and one or more discharges paths (e.g., the fifth discharge path 706e of FIG. 7A) are configured to discharge a backup capacitor (e.g., backup capacitor 616 of FIG. 6) of the PLP circuit.

In some implementations, in response to determining that the output voltage of the PLP circuit is lower than the first threshold but higher than a second threshold (e.g., a voltage between 0.5V and 1.5V), the discharge circuit can discharge the output of the PLP circuit through the first discharge path 706a.

In some implementations, in response to determining that the output voltage of the PLP circuit is lower than the second threshold and that the voltage of the backup capacitor is higher than a third threshold (e.g., a voltage between 1.2V and 2.5V), the discharge circuit can discharge the output of the PLP circuit through the fourth discharge path 706d.

In some implementations, the discharge circuit is coupled to the output of the PLP circuit. The discharge circuit can be a discrete circuit that is distanced from the PLP circuit on a printed circuit board.

At 1104, in response to determining that the output voltage of the PLP circuit is higher than a fourth threshold (e.g., a voltage between 1V and 4V) and lower than the first threshold, the discharge circuit can discharge the PLP circuit through the first discharge path 706a.

For example, during a power-on process when external power source is connected but unstable, the output volage of the PLP circuit may increase due to the accumulation of the unstable power supply. When the output voltage of the PLP circuit increases over the fourth threshold, the output of the PLP circuit can be discharged through the first discharge path 706a, so that the power-on sequence in the memory system is not disturbed by the unstable power supply.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting, information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory system, comprising:
a memory device comprising memory cells,
a memory controller coupled to the memory device,
a power loss protection (PLP) circuit, and
a discharge circuit coupled to an output of the PLP circuit, wherein the discharge circuit comprises one or more discharge paths configured to discharge at least one of the PLP circuit, the memory device, or the memory controller.

2. The memory system of claim 1, wherein a first discharge path of the one or more discharge paths comprises:
a first resistor coupled to the output of the PLP circuit, and
a first transistor coupled to a first switch transistor, wherein a gate of the first switch transistor is coupled to a first voltage dividing circuit, wherein the first voltage dividing circuit is configured to generate a divided voltage of the output of the PLP circuit, and wherein a terminal of the first switch transistor is coupled to the output of the PLP circuit.

3. The memory system of claim 2, wherein the first voltage dividing circuit comprises two resistors connected in series, wherein a first end of the first voltage dividing circuit is coupled to the output of the PLP circuit, and a second end of the first voltage dividing circuit is coupled to ground.

4. The memory system of claim 2, wherein a second discharge path of the one or more discharge paths comprises:
a second resistor coupled to an enable pin of a voltage converter configured to activate the voltage converter, wherein the voltage converter is configured to generate a voltage for the memory controller based on the output of the PLP circuit, and
a second transistor coupled to the first switch transistor.

5. The memory system of claim 2, wherein a third discharge path of the one or more discharge paths comprises:
a third resistor coupled to the memory device, and
a third transistor coupled to the first switch transistor.

6. The memory system of claim 2, wherein the PLP circuit comprises a capacitor, wherein the PLP circuit is configured to:
charge the capacitor when an external power source is turned on, and
discharge the capacitor to provide power for the memory system when the external power source is turned off.

7. The memory system of claim 6, wherein a fourth discharge path of the one or more discharge paths comprises:
a fourth resistor coupled to the output of the PLP circuit, and
a fourth transistor coupled to a second switch transistor, wherein a gate of the second switch transistor is coupled to the first voltage dividing circuit, and wherein a terminal of the second switch transistor is coupled to a second voltage dividing circuit configured to generate a divided voltage of a voltage of the capacitor.

8. The memory system of claim 7, wherein a fifth discharge path of the one or more discharge paths comprises:
a fifth resistor coupled to the capacitor, and
a fifth transistor coupled to the second switch transistor.

9. The memory system of claim 1, wherein the memory device, the memory controller, the PLP circuit and the discharge circuit are placed on a printed circuit board, wherein the discharge circuit is distanced from the PLP circuit on the printed circuit board.

10. The memory system of claim 8, wherein the discharge circuit is coupled to at least one of:
a capacitor of the PLP circuit,
an enable pin of a voltage converter, and
the memory device.

11. A memory system, comprising:
a memory device comprising memory cells,
a memory controller coupled to the memory device,
a power loss protection (PLP) circuit configured to provide power for the memory system when an external power source is turned off, and
a discharge circuit configured to:
in response to determining that an output voltage of the PLP circuit is lower than a first threshold, discharge at least one of the PLP circuit, the memory device or the memory controller.

12. The memory system of claim 11, wherein the discharge circuit comprises one or more discharge paths each comprising a transistor and a resistor.

13. The memory system of claim 12, wherein discharging at least one of the PLP circuit, the memory device or the memory controller comprises:
discharging the PLP circuit through a first discharge path of the discharge circuit,
discharging a first voltage line through a second discharge path of the discharge circuit, wherein the first voltage line is configured to activate a voltage converter configured to generate a voltage for the memory controller based on the output voltage of the PLP circuit, and
discharging a second voltage line through a third discharge path of the discharge circuit, wherein the second voltage line is configured to provide power for the memory device.

14. The memory system of claim 13, wherein the PLP circuit comprises a capacitor, and wherein the discharge circuit is configured to:
in response to determining that the output voltage of the PLP circuit is lower than a second threshold and that a voltage of the capacitor is higher than a third threshold:
discharge the PLP circuit through a fourth discharge path of the discharge circuit, and
discharge the capacitor through a fifth discharge path of the discharge circuit.

15. The memory system of claim 13, wherein the discharge circuit is configured to:
in response to determining that the output voltage of the PLP circuit is higher than a fourth threshold and lower than the first threshold, discharge the PLP circuit through the first discharge path.

16. The memory system of claim 14, wherein the first discharge path, the second discharge path and the third discharge path are coupled to a first switch transistor,
wherein a gate of the first switch transistor is coupled to a first voltage dividing circuit configured to generate a divided voltage of the output voltage of the PLP circuit, and wherein a terminal of the first switch transistor is coupled to an output of the PLP circuit.

17. The memory system of claim 16, wherein the fourth discharge path and the fifth discharge path are coupled to a second switch transistor,
wherein a gate of the second switch transistor is coupled to the first voltage dividing circuit, wherein a terminal of the second switch transistor is coupled to a second voltage dividing circuit configured to generate a divided voltage of a voltage of the capacitor.

18. A method of discharging a memory system, comprising:
in response to determining that an output voltage of a power loss protection (PLP) circuit of the memory system is lower than a first threshold, discharging, by a discharge circuit, at least one of the PLP circuit, a memory device of the memory system, or a memory controller of the memory system,
wherein the discharge circuit is distanced from the PLP circuit.

19. The method of claim 18, wherein discharging at least one of the PLP circuit, the memory device or the memory controller comprises:
in response to determining that the output voltage of the PLP circuit is lower than the first threshold, discharging the PLP circuit through a first discharge path of the discharge circuit, and
in response to determining that the output voltage of the PLP circuit is lower than a second threshold and that a voltage of a capacitor of the PLP circuit is higher than a third threshold, discharging the PLP circuit through a fourth discharge path of the discharge circuit.

20. The method of claim 19, comprising:
in response to determining that the output voltage of the PLP circuit is higher than a fourth threshold and lower than the first threshold, discharging the PLP circuit through the first discharge path.
